(19) United States
(12) Patent Application Publication
(10) Pub. No.: US 2022/0238430 A1
(43) Pub. Date: Jul. 28, 2022

(54) CAPACITOR STRUCTURE, SEMICONDUCTOR STRUCTURE, AND METHOD FOR MANUFACTURING THEREOF

(71) Applicant: AP MEMORY TECHNOLOGY CORPORATION, Hsinchu County (TW)

(72) Inventor: WENLIANG CHEN, HSINCHU COUNTY (TW)

(21) Appl. No.: 17/721,675

(22) Filed: Apr. 15, 2022

Related U.S. Application Data
(63) Continuation-in-part of application No. 17/511,190, filed on Oct. 26, 2021.
Application No. 17/511,190 is a continuation-in-part of application No. 17/085,770, filed on Oct. 30, 2020.
Application No. 17/085,770 is a continuation-in-part of application No. 16/609,159, filed on Oct. 28, 2019, now Pat. No. 11,038,012.
(60) Provisional application No. 63/209,923, filed on Jun. 11, 2021.
(60) Provisional application No. 63/209,923, filed on Jun. 11, 2021.
(60) Provisional application No. 63/283,112, filed on Nov. 24, 2021.

(51) Int. Cl. H01L 23/522; H01L 49/02; H01L 23/48; H01L 21/768

(52) U.S. Cl. CPC H01L 23/5223; H01L 21/76898; H01L 23/481; H01L 28/60

(57) ABSTRACT

A capacitor structure is provided. The capacitor structure includes a substrate, a middle-of-line (MEOL) structure, and a metallization structure. The substrate has a first surface and a second surface opposite to the first surface. The MEOL structure is over the first surface of the substrate. The MEOL structure includes a capacitor, and the capacitor includes a bottom plate and a top plate over the bottom metal plate. The metallization structure is over the MEOL structure. The substrate further includes a plurality of first through vias extending from the second surface of the substrate to the bottom metal plate. The semiconductor structure including the capacitor structure and the method for manufacturing the semiconductor structure are also provided.

### PRIORITY CLAIM AND CROSS-REFERENCE

This application claims the benefit of prior-filed U.S. provisional application No. 63/209,923, filed Jun. 11, 2021, and U.S. provisional application No. 63/283,112, filed Nov. 24, 2021, and incorporates them entirety herein.

This application is a continuation-in-part of pending U.S. application Ser. No. 17/511,190, filed Oct. 26, 2021, which is a continuation-in-part of pending U.S. application Ser. No. 17/085,770, filed Oct. 30, 2020, which is a continuation-in-part of granted U.S. application Ser. No. 16/609,159, filed Oct. 28, 2019, which is a National Phase of PCT/JP2017/016977, filed Apr. 28, 2017, the entire contents of which is incorporated herein by reference.

### FIELD

The present disclosure relates to a capacitor structure, a semiconductor structure, and method for manufacturing thereof, particularly, the disclosed capacitor structure includes a plurality of backside TSVs connected to the bottom plate of the capacitor in the capacitor structure, and thus the resistance of the bottom plate can be reduce.

### BACKGROUND

Integrated circuits (IC) generally include a variety of passive components. Capacitors are among some of the more common passive components that are widely used in ICs for various applications, for example, mixed signal applications such as filters and analog-to-digital converters. Switched-capacitor circuits, for instance, are widely used in mixed-signal, analog-to-digital interfaces. Switched-capacitor circuits are typically used to perform a variety of functions, among others, sampling, filtering and digitization of signals.

Two capacitor structures that are widely used for such circuits are the metal-insulator-metal (MIM) capacitor and the metal-oxide-metal (MOM) capacitor. Generally, MIM capacitors include an insulator sandwiched between two layers of metals while MOM capacitors are composed of a large number of parallel fingers or electrodes formed on numerous metal layers.

### BRIEF DESCRIPTION OF THE DRAWINGS

Aspects of the present disclosure are best understood from the following detailed description when read with the accompanying figures. It is noted that, in accordance with the standard practice in the industry, various structures are not drawn to scale. In fact, the dimensions of the various structures may be arbitrarily increased or reduced for clarity of discussion.

FIG. 1A illustrates a cross-sectional view of a semiconductor structure according to some comparative embodiments of the present disclosure.

FIG. 1B illustrates a cross-sectional view of a capacitor structure according to some comparative embodiments of the present disclosure.

FIG. 1C illustrates a top view of a capacitor according to some comparative embodiments of the present disclosure.

FIG. 2 illustrates a cross-sectional view of a capacitor structure according to some embodiments of the present disclosure.

FIG. 3 illustrates a cross-sectional view of a capacitor structure according to some embodiments of the present disclosure.

FIG. 4 illustrates a cross-sectional view of a semiconductor structure according to some embodiments of the present disclosure.

FIG. 5 illustrates a cross-sectional view of a capacitor structure according to some embodiments of the present disclosure.

FIG. 6 illustrates a cross-sectional view of a semiconductor structure according to some embodiments of the present disclosure.

FIG. 7 illustrates a cross-sectional view of a semiconductor structure according to some embodiments of the present disclosure.

FIG. 8 illustrates a cross-sectional view of a semiconductor structure according to some embodiments of the present disclosure.

FIG. 9A illustrates a cross-sectional view of a semiconductor structure according to some embodiments of the present disclosure.

FIG. 9B illustrates a cross-sectional view of a semiconductor structure according to some embodiments of the present disclosure.

FIGS. 10A and 10B illustrate cross-sectional views of forming a capacitor structure according to some embodiments of the present disclosure.

FIGS. 11A to 11D illustrate cross-sectional views of forming a capacitor structure according to some embodiments of the present disclosure.

FIGS. 12A to 12C illustrate cross-sectional views of forming a capacitor structure according to some embodiments of the present disclosure.

FIGS. 13A to 13E illustrate cross-sectional views of forming a capacitor structure according to some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper”, “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first”, “second” and “third” describe various elements, components, regions, layers and/or sections, these elements, components, regions, layers and/or sections should not be limited by these terms. These terms may be only used to distinguish one element, component, region, layer, or section from another. The terms such as “first”, “second”, and “third” when used herein do not imply a sequence or order unless clearly indicated by the context.

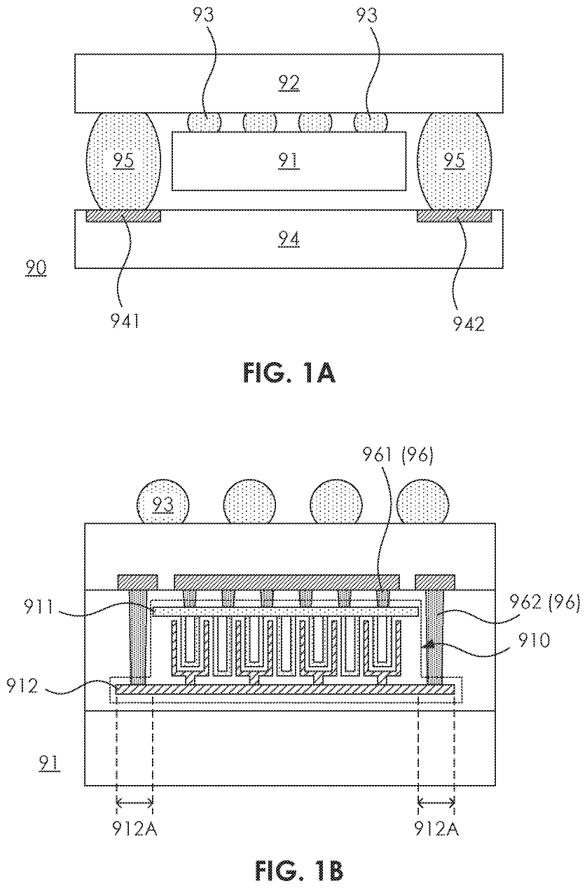

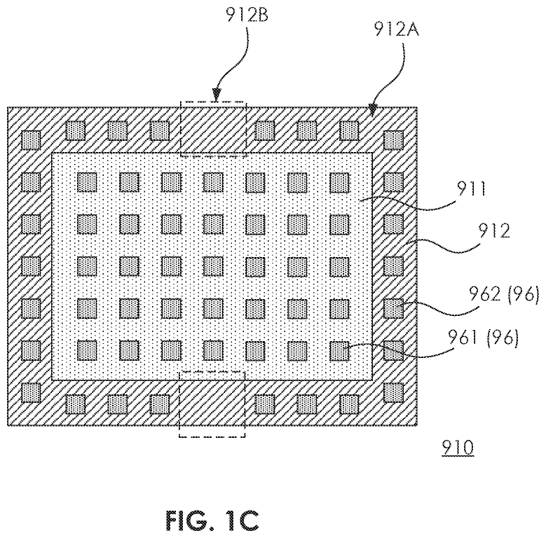

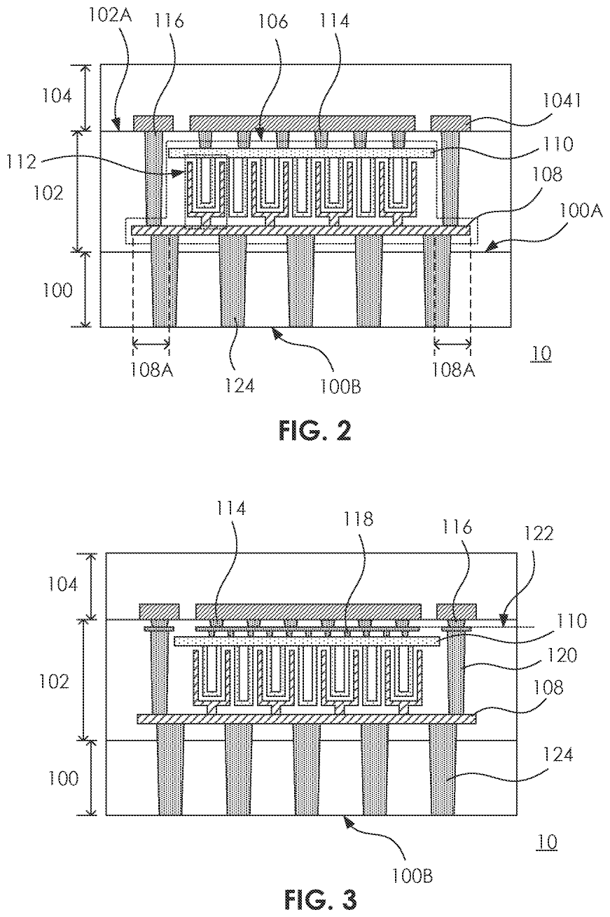

FIG. 1A illustrates a comparative embodiment that a semiconductor structure 90 which includes a capacitor structure 91 bonded with to a semiconductor chip 92. The semiconductor chip 92 could be a logic SOC, and the capacitor structure 91 bonded thereto may be used to reduce power supply fluctuation. For example, IC power consumption may be as high as about 100 W/cm² in high performance computing, which requires a large number of decoupling capacitors for lowering Effective Series Resistance (ESR) and Equivalent Series Inductance (ESL). In an ideal case, the capacitance should be infinity (i.e., as large as possible) while ESR and ESL should be zero (i.e., as small as possible).

In a comparative embodiment shown in FIGS. 1A and 1B, the capacitor structure 91 includes a capacitor 910 therein, such as a metal-insulator-metal (MIM) stack capacitor or metal-oxide-metal (MOM) interdigitated capacitor illustrated in FIG. 1B. The capacitor structure 91 can be electrically connected to the semiconductor chip 92 through a plurality of micro bumps 93 over a side the capacitor structure 91. Since the capacitor structure 91 is bonded on a surface of the semiconductor chip 92, a portion of the surface of the semiconductor chip 92 which facing a packaging substrate 94 is thus covered or shielded by the capacitor structure 91. Accordingly, the semiconductor chip 92 is packaged to the packaging substrate 94 through a plurality of conductive bumps 95 that laterally adjacent to the capacitor structure 91. In some embodiments, the conductive bumps 95 can be C4 bumps. As shown in FIG. 1A, the capacitor structure 91 does not directly connect to the packaging substrate 94, instead, the conductive bumps 95 are formed in contact with the VSS pad 941 and the VDD pad 942 of the packaging substrate 94 to electrically connect the semiconductor chip 92 and the packaging substrate 94. In other words, there is no conductive connections directly formed between the capacitor structure 91 and the packaging substrate 94, hence in such comparative embodiment, the transmission of the power and the signal of the semiconductor chip 92 must pass through the conductive bumps 95 that laterally adjacent to the capacitor structure 91.

Referring to a top view of the capacitor 910 in the capacitor structure 91 bonded on the semiconductor chip 92 illustrated in FIG. 1C, in the comparative embodiment, the capacitor 910 includes connection terminals at two sides thereof, for example, a top capacitor metal 911 and a bottom capacitor metal 912 can be formed to be electrically connected to the semiconductor chip 92. In such embodiment, the area of the bottom capacitor metal 912 is greater than the area of the top capacitor metal 911, and an uncovered region 912A of the bottom capacitor metal 912 is free from being covered by the top capacitor metal 911. Accordingly, the conductive vias 96 between the semiconductor chip 92 and the capacitor structure 91 can be formed on the entire area of the top capacitor metal 911 and the peripheral area (i.e., uncovered region 912A) of the bottom capacitor metal 912, which means the amount of the conductive vias 96 landing on the uncovered region 912A of the bottom capacitor metal 912 (e.g., conductive vias 962), generally, is far fewer than the amount of the conductive vias 96 landing on the top surface of the top capacitor metal 911 (e.g., conductive vias 961). Hence, the area limitation of uncovered region 912A is the bottleneck in lowering the plate resistance of the bottom capacitor metal 912.

In some example, the bottom capacitor metal 912 further includes one or more series connection regions 912B configured to connect with other capacitors 910. These series connection regions 912B are portions of the uncovered region 912A but they are left for forming the structures for series connection.

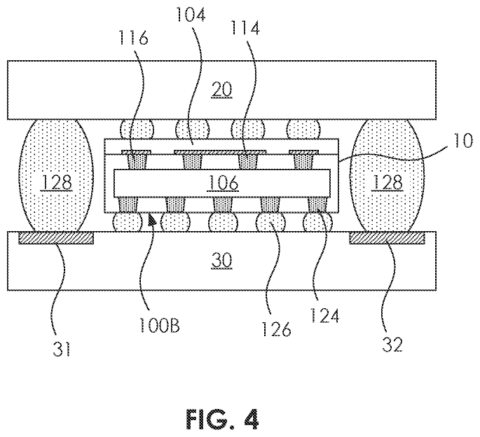

Referring to FIG. 2, in some embodiments of the present disclosure, a capacitor structure 10 that has an improved bottom plate resistance is provided. In such embodiments, the capacitor structure 10 includes a substrate 100, a middle-of-line (MOL/MEOL) structure 102, and a back-end-of-line (BEOL) structure 104. The substrate 100 has a first surface 100A and a second surface 100B opposite to the first surface 100A. In some embodiments, the substrate 100 is made of semiconductor materials such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, and the like, may also be used. In some embodiments, the substrate 100 is made of glass.

The MEOL structure 102 is a wiring portion of the capacitor structure 10, which is formed prior to the formation of the BEOL structure 104 (i.e., the metallization structure). The definitions of what is properly considered MEOL may vary, whereas in the embodiments of the present disclosure, the MEOL structure 102 is referred to the region that formed over the first surface 100A of the substrate 100 and until a first metal layer (M1) 1041 of the BEOL structure 104. The upper metal layers that above the first metal layer 1041 in the BEOL structure 104 are not shown in the drawings of the present disclosure for brevity. In some embodiments, the MEOL structure 102 is made of dielectric material, which may be referred to as a pre-metal dielectric (PMD). In other words, the MEOL structure 102 can be distinguished from the substrate 100 therebelow and the BEOL structure thereon by a number of process parameters, such as the choice of the fundamental material, or the choice of the metal used. For instance, the material of the MEOL structure 102 can be low-k dielectric material with a small dielectric constant relative to silicon dioxide, and thus can be distinguished from the material of the substrate 100; likewise, the metal usually used in the MEOL structure 102 for electrical connect is tungsten, while the metal usually used in the BEOL structure is copper. These are several exemplary approaches to distinguish the stacked layers in the capacitor structure, but the present embodiments are not be limited thereto.

Referring to FIG. 2, in some embodiments, a capacitor 106 is embedded in the MEOL structure 102. In some embodiments, the capacitor 106 can be a 3D metal insulator metal capacitor, while such out-of-plane dimension can be advantageously used to increase effective MIM area and related capacitance density. In some embodiments, the capacitor 106 in the present disclosure may have a very high density, for example, the capacitor density can be higher than about 1 μF/mm². In some embodiments, the 3D capacitor can be a cylinder capacitor.

As shown in FIG. 2, in some embodiments, the capacitor 106 includes a bottom plate 108, a top plate 110 over the bottom plate 108, and a plurality of capacitor cells 112 formed between the bottom plate 108 and the top plate 110. In some embodiments, the distance between the bottom plate 108 and the top plate 110 is in a range of from about 1 μm to about 2 μm.

In some embodiments, the bottom plate 108 and the top plate 110 are formed in different depths of the MEOL structure 102 and be arranged in parallel. In some embodiments, because the bottom plate 108 is formed in proximity to the first surface 100A of the substrate 100, a distance between the bottom plate 108 and the substrate 100 is less than a distance between the top plate 110 and the substrate 100. In some embodiments, a planar area of the bottom plate 108 is greater than a planar area of the top plate 110 from a top view perspective, and therefore, like the previously mentioned comparative embodiment shown in FIGS. 1B and 1C, a peripheral area, or called an uncovered region 108A of the bottom plate 108, is free from being covered by the top plate 110.

In order to electrically connect the capacitor 106 with other semiconductor structures or semiconductor devices, in some embodiments of the present disclosure, both of the upper side and the lower side of the capacitor 106 are in contact with a plurality of conductive contacts or vias to provide electrical connections at a top surface 102A of the MEOL structure 102 and the second surface 100B of the substrate 100. In other words, the conductive contacts or vias used to couple to the capacitor 106 in the present disclosure can be formed both over and under the capacitor 106, which means the space below the capacitor 106 can also be used effectively.

Still referring to FIG. 2, the capacitor structure 10 can include a plurality of first metal contacts 114 and a plurality of second metal contacts 116 over the capacitor 106. The first metal contacts 114 are directly landed on the top surface of the top plate 110, and the second metal contacts 116 are directly landed on the uncovered region 108A of the bottom plate 108 that is free from being covered by the top plate 110. In such embodiment, the first metal contact 114 and the second metal contact 116 are different in vertical lengths.

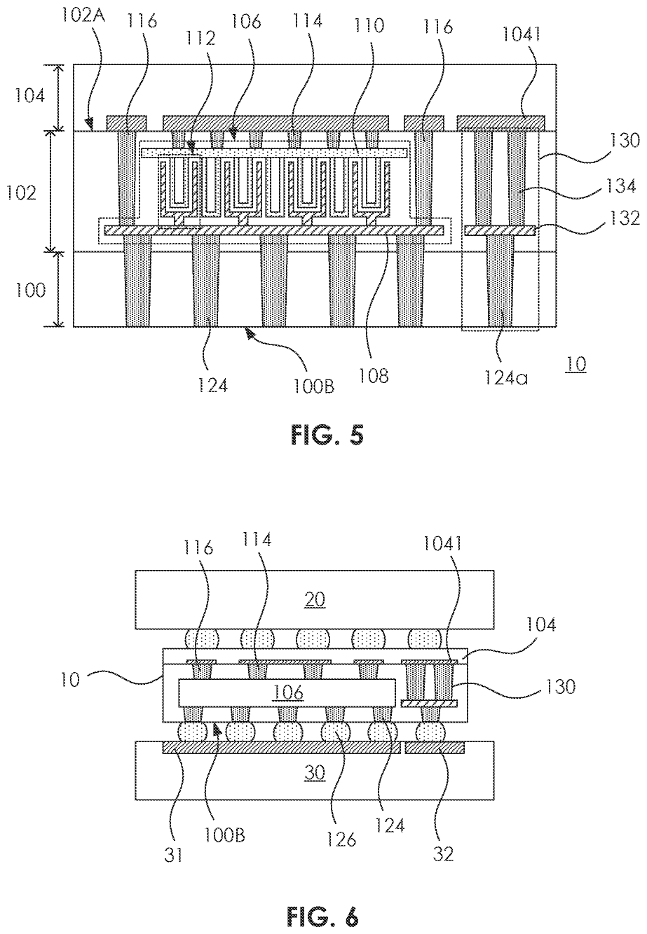

Referring to FIG. 3, in some embodiments, in order to reduce the failure of landing or unwanted shifting of the first and second metal contacts 114, 116, the MEOL structure 102 can include a first capacitor electrode structure 118 in contact with the top surface of the top plate 110, and a second capacitor electrode structure 120 in contact with the uncovered region 108A of the bottom plate 108. In some embodiments, the first capacitor electrode structure 118 and the second capacitor electrode structure 120 can provide a coplanar contacting surface 122 over the capacitor 106 (see the dot line illustrated in FIG. 2) for the contact landing of the first and second metal contacts 114, 116. That is, in such embodiments, the first metal contacts 114 and the second metal contacts 116 are substantially identical in vertical lengths. In some embodiments, each of the first capacitor electrode structure 118 or the second capacitor electrode structure 120 includes a combination of a capacitor contact and a capacitor pad. In some embodiments, the height of the second capacitor electrode structure 120 is greater than the height of the first capacitor electrode structure 118.

As shown in FIG. 2 and FIG. 3, in some embodiments, the capacitor structure 10 further includes a plurality of first through vias 124 extending from the second surface 100B of the substrate 100 to the bottom plate 108. These first through vias 124 can be called backside TSVs, which are formed under the capacitor 106 and can be used to improve the resistance of the bottom plate 108 of the capacitor 106. That is, w because a significant area ratio of the bottom plate 108 is already covered by the plurality of capacitor cells 112 and the top plate 110 in the MEOL structure 102, accordingly, the present disclosure uses the backside of the bottom plate 108 (i.e., the side in proximity to the substrate 100) to increase the area be coupled with conductive vias or contacts, and the resistance of the bottom plate 108 is lowered thereby.

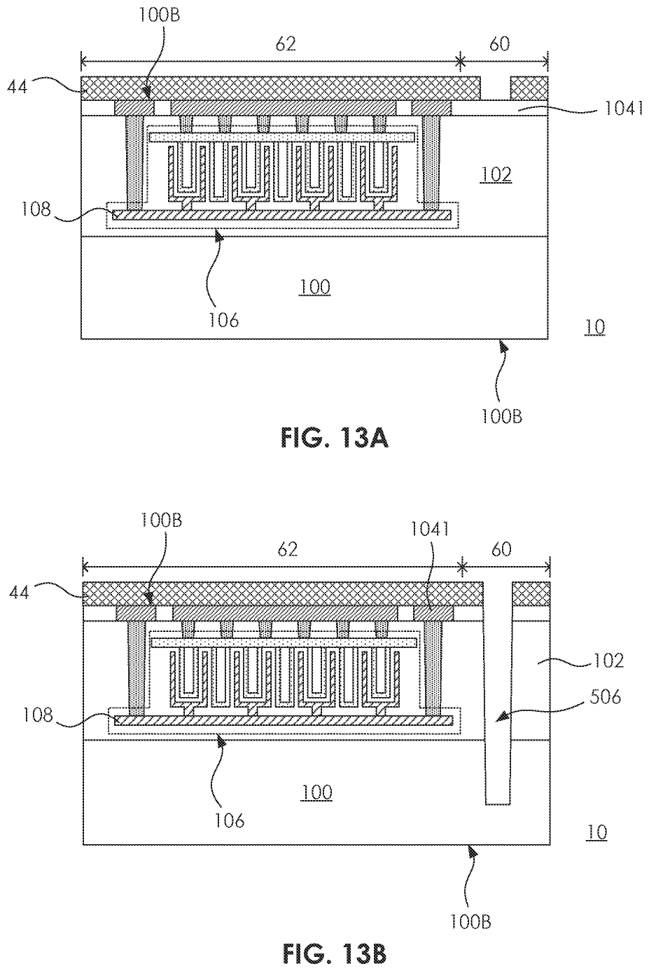

As shown in FIG. 2 and FIG. 3, the first through vias 124 are through silicon vias (TSV) that perpetrate the substrate 100. In the circumstances that the substrate 100 is made by the semiconductor material, a oxide liner (latter shown in FIG. 11C) made by dielectric materials (e.g., an oxide material) can be formed to laterally surround the first through vias 124 in preventing leakage current in the substrate 100. In other circumstances that the substrate 100 is made by non-conductive material such as glass, the first through vias 124 can directly contact the substrate 100, and the formation of the oxide liner can be waived.

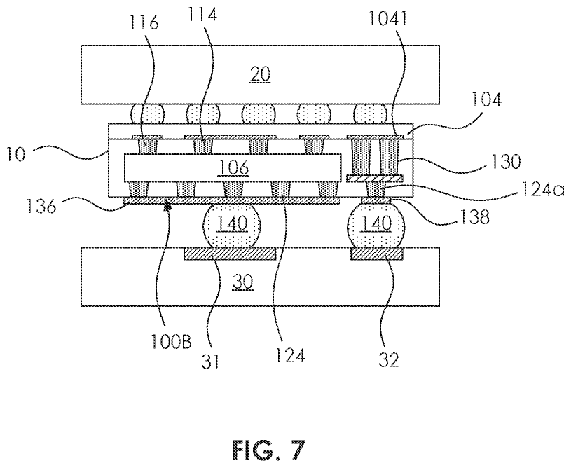

Referring to FIG. 4, in some embodiments, an end of each first through via 124 is in contact with the bottom of the capacitor 106 (i.e., the bottom surface of the bottom plate 108), while another end of each first through via 124 is exposed at the second surface 100B of the substrate 100 of the capacitor structure 10 for electrical connection. The details of the capacitor 106 may refer to the embodiments shown in FIG. 2 and FIG. 3. In some embodiments, the capacitor structure 10 is bonded to a semiconductor device 20 (e.g., a logic SOC, logic die, logic chip, or the like) through micro bumps or other bonding techniques such as a hybrid bonding structure. The bonded structure is further bonded on a package substrate 30 or an interposer through the direct connections of the first through vias 124 and a plurality of conductive terminals 126. In some embodiments, the conductive terminals 126 may include micro bumps, C4 bumps, solder balls, or the like.

Furthermore, in some embodiments, a plurality of conductive bumps 128 can be formed between the semiconductor device 20 and the package substrate 30 to directly connect the semiconductor device 20 and the package substrate 30. In some embodiments, the conductive bumps 128 can be C4 bumps. In some embodiments, the conductive bumps 128 can be used to in contact with the VSS pad 31 and the VDD pad 32 of the package substrate 30.

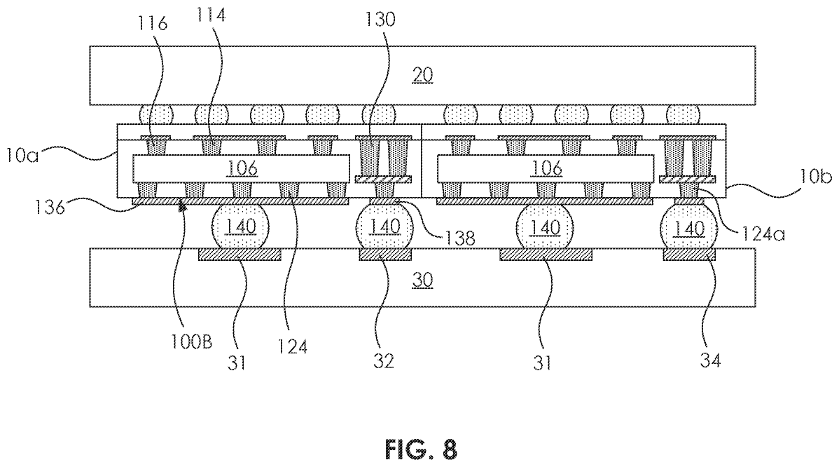

Referring to FIG. 5, in some embodiments, a feed-through connection structure 130 can be formed in the MEOL structure 102 and the substrate 100 of the capacitor structure 10. As shown in the figure, the feed-through connection structure 130 is adjacent to the capacitor 106 and the first and second metal contacts 114, 116 and the first through vias 124 contacted thereto. The feed-through connection structure 130 can be used to provide a short path for the electrical connection between the semiconductor device 20 and the portion that directly below the capacitor structure 10. In some embodiments, the feed-through connection structure 130 includes a relay metal 132 leveled with the bottom plate 108. The relay metal 132 can be used as a landing base for one or more third metal contacts 134 formed thereon. In such embodiments, the length of each second metal contacts 116 is identical to the length of the third metal contact 134. In some embodiments, the feed-through connection structure 130 includes one or more second through vias 124a extending from the relay metal 132 to the second surface 100B of the substrate 100.

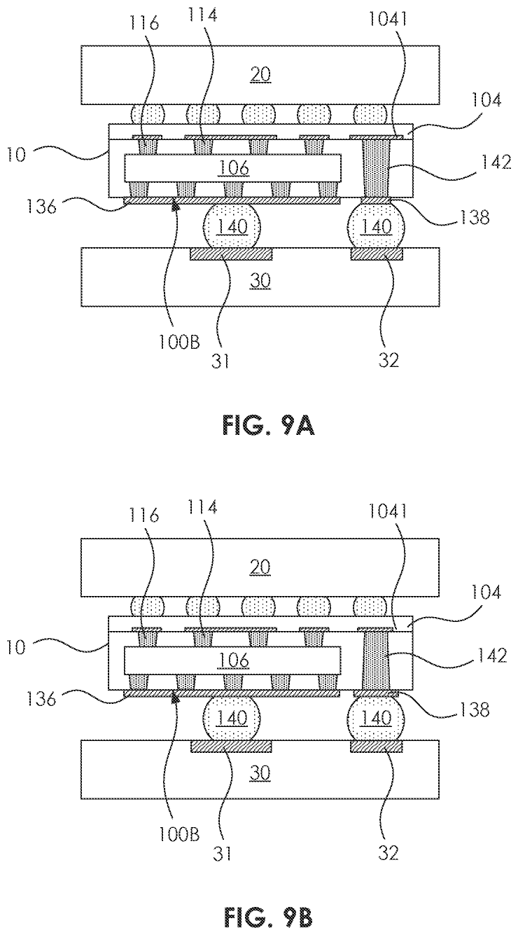

FIG. 6 is a cross-sectional view of a semiconductor structure that which the capacitor structure 10 is bonded between the semiconductor device 20 and the package substrate 30 according to some embodiments of the present disclosure. Referring to the detail of the capacitor structure 10 shown in FIG. 5 and the bonded structure shown in FIG. 6, a top end of the feed-through connection structure 130 can be in contact with the first metal layer 1041 of the BEOL structure 104, a bottom end of the feed-through connection structure 130 be exposed at the second surface 100B of the substrate 100 to in contact the conductive terminal 126 between the capacitor structure 10 and the package substrate 30.

As the embodiment shown in FIG. 5 and FIG. 6, the VSS pad 31 and the VDD pad 32 of the package substrate 30 can be arranged directly below the capacitor structure 10. For example, the VDD pad 32 can be arranged directly below the feed-through connection structure 130 and be electrically connected to the feed-through connection structure 130 by one or more conductive terminals 126 therebetween; whereas the VSS pad 31 can be arranged directly below the capacitor 106 and be electrically connected thereto by one or more conductive terminals 126 therebetween. Accordingly, by using the feed-through connection structure 130, the power supply to the capacitor structure 10 and the semiconductor device 20 can be performed by the VSS pad 31 and the VDD pad 32 directly below, which means the use of some of the conductive bumps 128 previously illustrated in FIG. 4 may be omitted. In the circumstances that the conductive bumps laterally surrounding the capacitor structure 10 are not formed, there may have more areas of the semiconductor device 20 that can be used to bond with more capacitor structures 10, and therefore, the density and the quantity of the capacitor can both be increased. In some alternative embodiments, the conductive bumps 128 can be formed between the capacitor structure 10 and the package substrate 30, that is, the feasible connection technique at the backside (i.e., the second surface 100B) of the capacitor structure 10 is various.

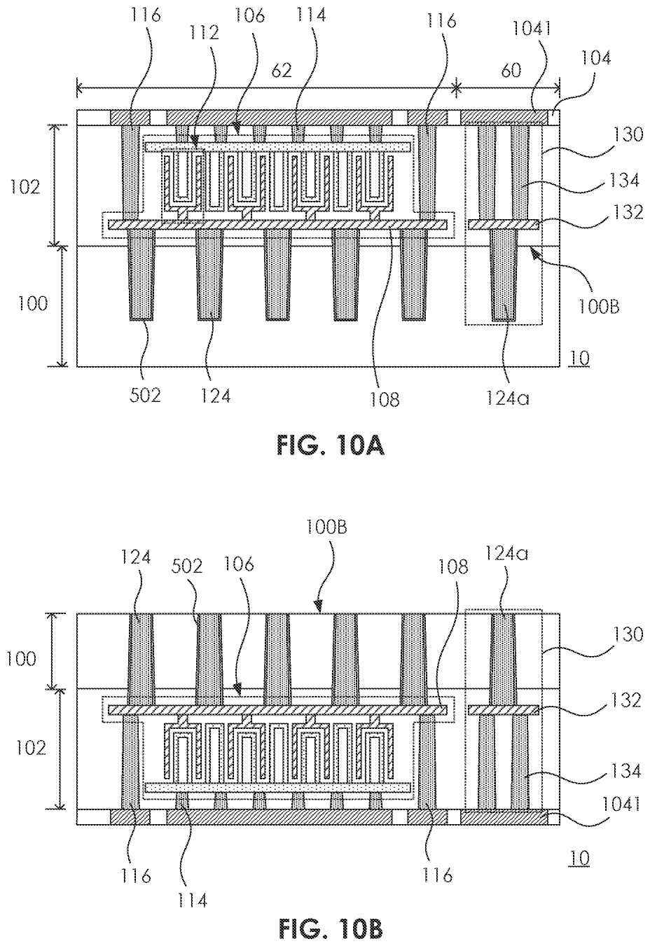

Further in some alternative embodiments, referring to FIG. 7, a redistribution layer can be formed on the second surface 100B of the substrate 100. For example, a first redistribution layer 136 can be formed to be in contact with the first through vias 124 below the capacitor 106, and a second redistribution layer 138 can be formed to in be contact with the second through vias 124a of the feed-through connection structure 130. Moreover, the first redistribution layer 136 and the VSS pad 31 can be connected by a conductive bump 140 such as C4 bump, solder ball, or the like. Likewise, the second redistribution layer 138 and the VDD pad 32 can be connected by another conductive bump 140.

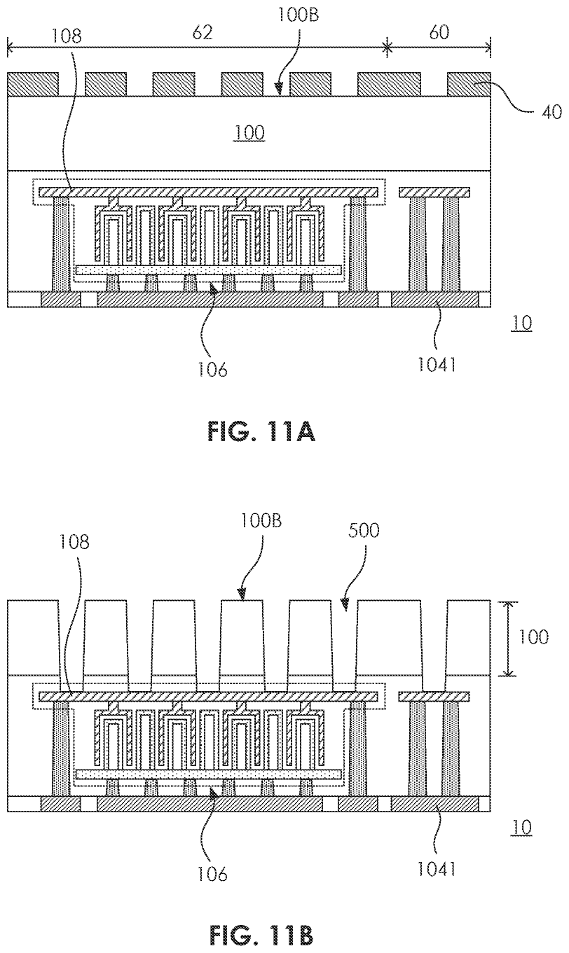

In some embodiments, a plurality of capacitor structures can be bonded between the semiconductor device 20 and the package substrate 30. Referring to FIG. 8, a first capacitor structure 10a and a second capacitor structure 10b are arranged be bonded between the semiconductor device 20 and the package substrate 30. The first capacitor structure 10a and the second capacitor structure 10b can be capacitor chiplet structures that diced from a capacitor wafer having a plurality of capacitor chiplet structures. In some embodiments, there is no need to dice the capacitor structures 10a, 10b from the capacitor wafer since they can be bonded between the semiconductor device 20 and the package substrate 30 as a single component.

In the embodiment shown in FIG. 8, the pads of the package substrate 30 can be designed to cooperate the combination of the capacitor chiplet structures bonded thereon. As shown in the figure, the VSS pads 31 can be arranged to electrically connect to the capacitor 106 through the conductive structures therebetween, and the VDD pad 32 below the first capacitor structure 10a is electrically connected to the feed-through connection structure 130. Different from that in the first capacitor structure 10a, the pad 34 of the package substrate 30 which in proximity to the feed-through connection structure 130 in the second capacitor structure 10b is a pad for signal transmission. That is, by forming TSVs (e.g., the first through vias 124 and/or the feed-through connection structure 130) at the backside of the capacitor structures 10a, 10b, these conductive paths can be used as a power rail or may provide signal connection to/from the semiconductor device 20 (e.g., logic SOC). In such embodiments, the first redistribution layer 136 is isolated from the second redistribution layer 138, and the electrical path including the second redistribution layer 138 may have a shortest distance between the semiconductor device 20 and the package substrate 30, which may provide a high speed, high bandwidth, and low resistance connection between the semiconductor device 20 and the package substrate 30. In other words, the feed-through connection structure 130 in the first capacitor structure 10a, for example, is isolated from the capacitor 106 in the first capacitor structure 10a, and therefore the signal or power does not go through the capacitor 106 in the first capacitor structure 10a.

Accordingly, based on these conductive paths, the circuit designs for the electrical communications between the capacitor chiplet structures, the semiconductor device, and/or the package substrate can be more flexible. For example, in the circumstance that the feed-through connection structures 130 in the capacitor structures 10a, 10b are configured to performed as a power rail and a signal line, respectively, the semiconductor device 20 can be free from in contact with conductive bumps (e.g., conductive bumps 128 previously shown in FIG. 4) that laterally adjacent to the capacitor structures 10a, 10b. Furthermore, because the length of the conductive paths can also be reduced, the latency and the power consumption of the semiconductor device can be improved as well.

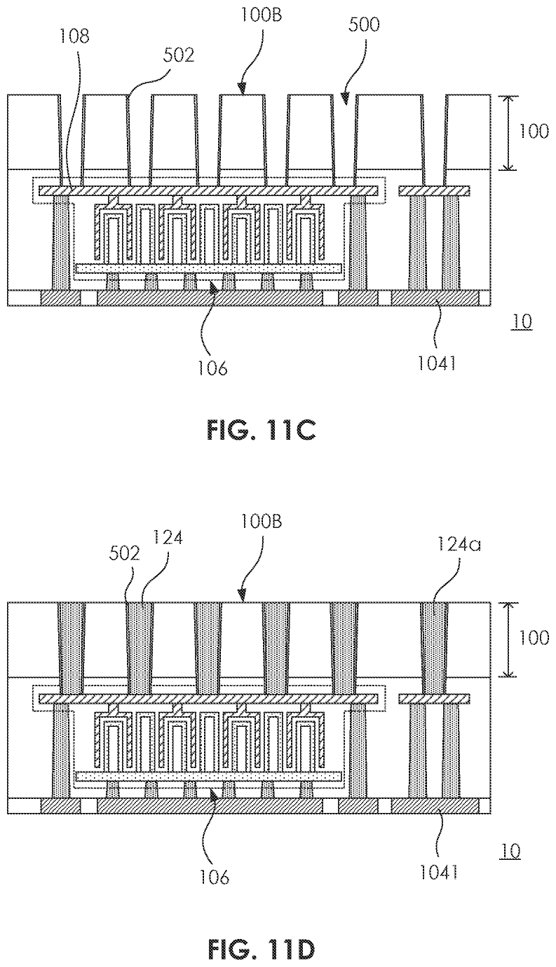

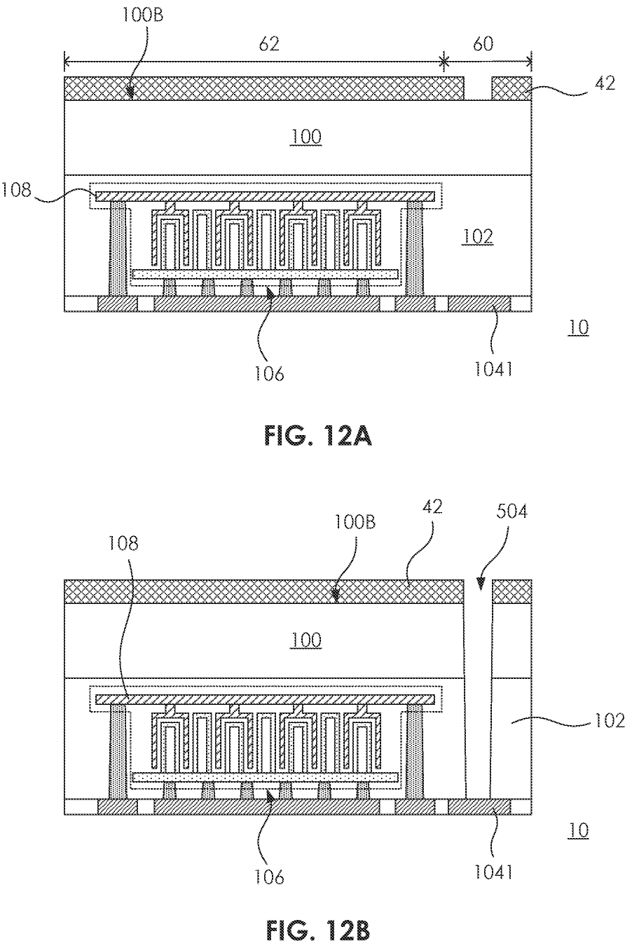

Referring to FIG. 9A and FIG. 9B, in some embodiments, a feed-through connection structure in the capacitor structure 10 is formed as a unitary structure. For example, the feed-through connection structure is consisting of a feed-through via 142 extending from the second surface 100B of the substrate 100 to the first metal layer 1041 of the BEOL structure 104. Generally, both the first through via 124 and the feed-through via 142 have tapered profiles from a cross-section view perspective due to the manufacturing method thereof. By forming the feed-through via 142 through different approaches, a narrower end of the feed-through via 142 can be in proximity to the second surface 100B of the substrate 100 (see the example shown in FIG. 9A) or in proximity to the first metal layer 1041 of the BEOL structure 104 (see the example shown in FIG. 9B).

Overall, the embodiments of the capacitor structures illustrated in the present disclosure include a plurality of electrical connections at the side having a substrate. These electrical connections may provide additional electrical paths of a bottom plate of a capacitor in each capacitor structure. Due to the coverage of a top metal plate, there are far fewer metal contacts can be landed on the upper side of the bottom metal plate, and therefore, the embodiments of the present disclosure use a plurality of backside TSVs that penetrate the substrate of the capacitor structure to in contact with the lower side of the bottom plate of the capacitor. Accordingly, the resistance of the bottom plate of the capacitor in each capacitor structure can be managed and adjusted by adding these backside TSVs. In other words, these backside TSVs are implemented in the present disclosure to reduce the resistance of the bottom plate of the capacitor in the capacitor structure, and these backside TSVs can also alter the path of power supply of the capacitor and/or the semiconductor device bonded with the capacitor, furthermore, an additional feed-through connection can also be provided based on the technique in forming backside TSVs. Consequently, the electrical performance of the semiconductor device can be improved because the latency and power consumption would be reduced, while the capacitor density, bandwidth would be increased thereby.

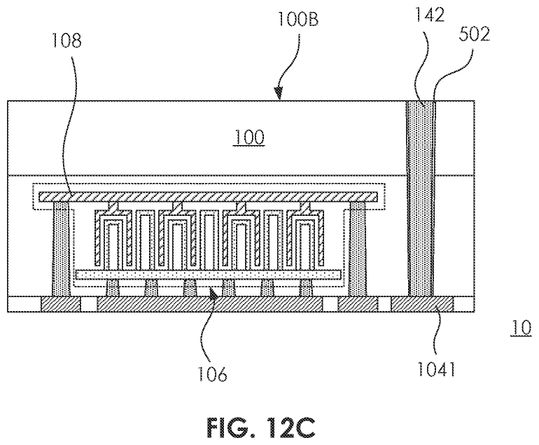

In manufacturing the capacitor structure 10 previously shown in FIG. 5, particularly, the operations to form the backside TSVs (i.e., the first through vias 124) extending from the backside (i.e., the second surface 100B of the substrate 100) of the capacitor structure 10, may refer to FIGS. 10A and 10B. As shown in FIG. 10A, a substrate 100 made by semiconductor material or glass can be received, and a first surface 100A of the substrate 100 is covered by a MEOL structure 102 formed thereon. Prior to forming the capacitors in the MEOL structure 102, a plurality of first through vias 124 are formed in the substrate 100 in advance. The bottom end of each first through vias 124 is embedded inside the substrate 100 because the thickness of the substrate 100 at the very beginning is much thicker than the length of the first through vias 124. The top end of each first through via 124 is in contact with a bottom plate 108 of a capacitor 106. In the scenario that a feed-through connection structure 130 is formed in the capacitor structure 10, particularly, in a feed-through region 60 of the substrate 100, a second through vias 124a is formed in the substrate 100, and a relay metal 132 is formed over the second through vias 124a and during forming the MEOL structure 102. An end of the second through vias 124a is in contact with the relay metal 132 accordingly. The relay metal 132 is leveled with the bottom plate 108 of the capacitor 106.

In addition, a plurality of first metal contacts 114 and a plurality of second contacts 116 are formed on the capacitor 106. In some embodiments, a plurality of third metal contacts 134 are formed on the relay metal 132 and leveled with the capacitor cells 112. In some embodiments, a first metal layer (M1) 1041 of a BEOL structure 104 is formed over the capacitor 106 and the third metal contacts 134. In some embodiments, the substrate 100 which shown in FIG. 10A is a portion of a wafer, and the MEOL structure 102 and the BEOL structure 104 are layers that formed on the wafer. The wafer can be diced to obtain a plurality of capacitor structures 10 in latter operations.

Referring to FIG. 10B, after receiving the substrate 100 which has the MEOL structure 102 and the BEOL structure 104 formed thereon, a backside thinning operation can be implemented to reveal the bottom end of each first through via 124. For example, the bottom end of the first through vias 124 are exposed by polishing or grinding operations employed from the second surface 100B of the substrate 100. In the method illustrated in FIGS. 10A and 10B, because the first through vias 124 are pre-manufactured in the substrate 100, the method in forming the backside TSVs can be called a via middle process.

After the capacitor structure 10 is prepared, a semiconductor device 20 can be bonded on the BEOL structure of the capacitor structure 10, and the substrate 100 of the capacitor structure 10 and the semiconductor device 20 can be mounted on a package substrate 30 through a plurality of conductive terminals 126 or conductive bumps 140 between the plurality of first through vias 124, the second through via 124a, and the package substrate 30. The bonded semiconductor structure may refer to the embodiment previously shown in FIG. 6 or FIG. 7.

As the structure previously shown in FIG. 7, in some embodiments, prior to mounting the substrate 100 of the capacitor structure 10 to the package substrate 30, a first redistribution layer 136 can be formed on the second surface 100B of the substrate 100 in a capacitor region 62 of the substrate 100 (see FIG. 10A), and a second redistribution layer 138 can be formed on the second surface 100B of the substrate 100 in a feed-through region 62 of the substrate 100 (see FIG. 10A). The first redistribution layer 136 is isolated from the second redistribution layer 138.

Different from the process in FIGS. 10A and 10B, in other embodiments, the backside TSVs can be manufactured after the formation of the capacitor 106. Referring to a via last process shown in FIGS. 11A to 11D, a substrate 100 made by semiconductor material or glass can be received, and a first surface 100A of the substrate 100 is covered by a MEOL structure 102 and a first metal layer (M1) 1041 of a BEOL structure 104 formed thereon, wherein the substrate 100 is free from having any first through vias 124 inside. Referring to FIG. 11A (the capacitor structure 10 is turned upside down for illustration), a photoresist layer 40 can be formed over the second surface 100B of the substrate 100, and the photoresist layer 40 is subsequently patterned to form the first through vias 124. Next, referring to FIG. 11B, a plurality of trenches 500 can be formed at the second surface 100B of the substrate 100 by a via etching operation for forming the first through vias 124. The substrate 100 can be thinned down in advance if the thickness thereof is not suit for the via etching operation. The pitch between the trenches 500 for forming the first through vias 124 can be tens of or dozens of micrometers. Generally, the density and the critical dimension of the first through vias 124 can be determined by the capability of the semiconductor process. On the other hand, because the TSV aspect ratio is related to the via etching technique, and therefore, generally, the thinner the substrate 100, the narrower the trenches 500 can be formed for forming the first through vias 124, hence an array of the first through vias 124 can thus have a high density.

After the via etching operation, a via filing operation can be implemented subsequently. As shown in FIG. 11D, a plurality of first through vias 124 can be formed by filling metal to the trenches 500. In some embodiments, as shown in FIG. 11C, an oxide liner 502 can be formed in the inner surface of each of the trenches 500 prior to the via filing operation. The oxide liner 502 is configured to prevent electrical leakage at the substrate 100. In the circumstance the bottom of the trench 500 is covered by the oxide liner 502, an additional etching operation can be implemented to clean the area for electrical connection. In the scenario that the substrate 100 is made by non-conductive material such as glass, the via filing operation can be directly implemented without the formation of the oxide liner. Furthermore, after the via filling operation, a CMP operation may be implemented to the second surface 100B of the substrate 100 to form a flat surface prior to forming electrical connections thereon.

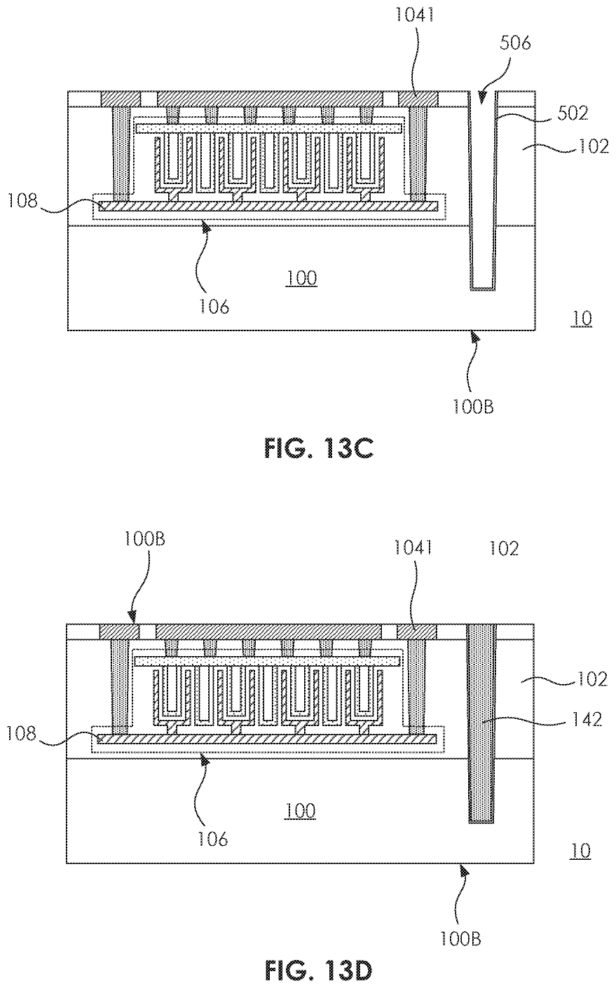

In the embodiments that the received substrate 100 does not include the third metal contacts 134 and the relay metal 132 that leveled with the capacitor cells 112, a feed-through connection structure that consisting of a feed-through via 142 extending from the second surface 100B of the substrate 100 to the first metal layer 1041 of the BEOL structure 104 can be formed in an independent process. As shown in FIGS. 12A to 12C (the capacitor structure 10 is turned upside down for illustration), a photoresist layer 42 can be formed over the second surface 100B of the substrate 100, and the photoresist layer 42 is subsequently patterned to form the feed-through via 142 in a feed-through region 60 of the substrate 100. The feed-through region 60 is other than a capacitor region 62 of the substrate 100 as illustrated in FIG. 12A. Next, as shown in FIG. 12B, a trench 504 is formed by implementing a via etching operation, and the trench 504 penetrates the substrate 100 and extends toward the MEOL structure 102. The position of trench 504 bypasses the capacitor 106 so that the latter formed through vias can be free from overlap with the capacitor 106. The trench 504 may be subsequently filled by a via filling operation. As illustrated in FIG. 12C, an oxide liner 502 can be formed prior to the via filling operation, depending on the material of the substrate 100.

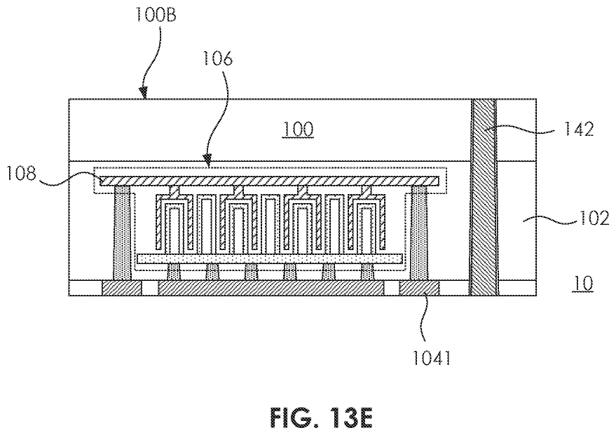

In other embodiments, the feed-through via 142 can be formed from a front side of the capacitor structure 10. For example, as shown in FIGS. 13A to 13E, a photoresist layer 44 can be formed over the first metal layer (M1) 1041 of the BEOL structure, and the photoresist layer 44 is patterned to form the feed-through via 142. Referring to FIG. 13B, a trench 506 is formed by implementing a via etching operation, wherein the trench 506 can penetrates the first metal layer 1041 and the MEOL structure 102, and the bottom of the trench 506 is stopped in the substrate 100. Next, referring to FIGS. 13C and 13D, the trench 506 may be subsequently filled by a via filling operation, while if it is necessary, the oxide liner 502 can be formed prior to the via filling operation for lateral insulation. Subsequently, as shown in FIG. 13E, the wafer can be flipped and a backside thinning operation can be implemented to thin down the substrate 100 from the second surface 100B, and the bottom of the feed-through via 142 can be revealed accordingly.

Briefly, according to the above-mentioned embodiments, the capacitor structure in the present disclosure includes backside TSVs that are connected to the bottom plate of the capacitor. These backside TSVs can provide additional electrical paths for the power supply of the capacitor, and the resistance of the bottom plate thereof is reduced accordingly. Furthermore, the backside TSV technique can be used to provide feed-through TSV that is not directly connected to the terminals of the capacitor, and the feed-through TSV can be performed to supply power to the semiconductor devices that bonded with the capacitor or to transmit signals therewith. As a result, not only the parameters of the capacitor are optimized, but the electrical performance of the semiconductor device is also be improved since the latency and power consumption can be reduced thereby.

In one exemplary aspect, a capacitor structure is provided. The capacitor structure includes a substrate, a middle-of-line (MEOL) structure, and a metallization structure. The substrate has a first surface and a second surface opposite to the first surface. The MEOL structure is over the first surface of the substrate. The MEOL structure includes a capacitor, and the capacitor includes a bottom plate and a top plate over the bottom metal plate. The metallization structure is over the MEOL structure. The substrate further includes a plurality of first through vias extending from the second surface of the substrate to the bottom metal plate.

In another exemplary aspect, a semiconductor structure is provided. The semiconductor structure includes a package substrate, a first capacitor structure, and a semiconductor device. The first capacitor structure is bonded over the package substrate. The first capacitor structure includes a capacitor, and the package substrate is electrically connected to the first capacitor structure through a plurality of first through vias extending from the capacitor to a backside of the first capacitor structure. The semiconductor device is bonded over the first capacitor structure.

In yet another exemplary aspect, a method for manufacturing a semiconductor structure is provided. The method includes the following operations. A substrate having a first surface and a second surface opposite to the first surface is provided. A middle-of-line (MEOL) structure is formed over the first surface of the substrate. The MEOL structure includes a capacitor, and the capacitor includes a bottom plate and a top plate over the bottom plate A plurality of first through vias are formed in the substrate and in contact with the bottom plate of the capacitor.

The foregoing outlines structures of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A capacitor structure, comprising:
a substrate having a first surface and a second surface opposite to the first surface;
a middle-of-line (MEOL) structure over the first surface of the substrate, the MEOL structure comprises a capacitor, and the capacitor comprises a bottom plate and a top plate (110) over the bottom plate;
a metallization structure over the MEOL structure;
wherein the substrate further comprises a plurality of first through vias extending from the second surface of the substrate to the bottom plate.

2. The capacitor structure of claim 1, wherein the MEOL structure further comprises:
a plurality of first metal contacts extending from the top plate of the capacitor to the metallization structure; and
a plurality of second metal contacts extending from the capacitor bottom plate of the capacitor to the metallization structure;
wherein the plurality of first metal contacts and the plurality of second metal contacts are in contact with a first metal layer (M1) of the metallization structure.

3. The capacitor structure of claim 1, wherein the MEOL structure further comprises:
a relay metal leveled with the bottom plate; and
a plurality of third metal contacts extending from the relay metal to the metallization structure.

4. The capacitor structure of claim 3, wherein the substrate further comprises a second through via extending from the second surface of the substrate to the relay metal.

5. The capacitor structure of claim 1, further comprising a feed-through connection structure extending from the second surface of the substrate to the metallization structure.

6. The capacitor structure of claim 1, further comprising a redistribution layer on the second surface and in contact with the plurality of first through vias.

7. The capacitor structure of claim 1, wherein each of the plurality of first through vias comprises a narrower end in proximity to the second surface of the substrate.

8. The capacitor structure of claim 1, wherein each of the plurality of first through vias comprises a narrower end in proximity to the bottom plate of the capacitor.

9. A semiconductor structure, comprising:
a package substrate;
a first capacitor structure bonded over the package substrate, wherein the first capacitor structure comprises a capacitor, and the package substrate is electrically connected to the first capacitor structure through a plurality of first through vias extending from the capacitor to a backside of the first capacitor structure; and
a semiconductor device bonded over the first capacitor structure.

10. The semiconductor structure of claim 9, wherein the capacitor comprises:
a bottom plate;
a top plate over the bottom plate, wherein a planar area of the top plate is less than a planar area of the bottom metal plate from a top view perspective; and
a plurality of capacitor cells between the bottom plate and the top plate;
wherein the plurality of first through vias are in contact with a bottom surface of the bottom plate.

11. The semiconductor structure of claim 9, wherein the first capacitor structure further comprises a first feed-through connection structure adjacent to the capacitor and the first through vias.

12. The semiconductor structure of claim 11, wherein the first feed-through connection structure comprises:
a relay metal leveling with the bottom plate;
a second through via extending from the relay metal to the backside of the first capacitor structure; and
a plurality of metal contacts landing on the relay metal.

13. The semiconductor structure of claim 12, wherein a length of the second through via is identical to a length of the first through via.

14. The semiconductor structure of claim 12, wherein the first feed-through connection structure in the first capacitor structure is isolated from the capacitor.

15. The semiconductor structure of claim 9, wherein each of the plurality of first through vias are laterally surrounded by an oxide liner.

16. A method for manufacturing a semiconductor structure, the method comprising:
providing a substrate having a first surface and a second surface opposite to the first surface;
forming a middle-of-line (MEOL) structure over the first surface of the substrate, the MEOL structure comprises a capacitor, and the capacitor comprises a bottom plate and a top plate over the bottom plate; and
forming a plurality of first through vias in the substrate and in contact with the bottom plate of the capacitor.

17. The method of claim 16, wherein forming the plurality of first through vias in the substrate is prior to forming the MEOL structure over the first surface of the substrate, and wherein a first end of each of the first through vias is embedded in the substrate, and a second end of each of the first through vias is exposed from a first surface of the substrate.

18. The method of claim 17, wherein the bottom plate of the capacitor is in contact with the second end of each of the first through vias, and the method further comprising:
thinning down the substrate from the second surface of the substrate to reveal the first end of each of the first through via.

19. The method of claim 16, further comprising:
forming a second through via in a feed-through region of the substrate; and
forming a relay metal over the second through via during forming the MEOL structure, wherein the relay metal is leveled with the bottom plate of the capacitor.

20. The method of claim 19, wherein forming the plurality of first through vias in the substrate is after forming the relay metal, and the plurality of first through vias are formed by a via etching operation and a via filling operation at the second surface of the substrate.
